(19) United States
(12) Patent Application Publication
(10) Pub. No.: US 2024/0162281 A1
(43) Pub. Date: May 16, 2024

(54) SEMICONDUCTOR DEVICE

(71) Applicant: Samsung Electronics Co., Ltd., Suwon-si (KR)

(72) Inventors: Intak JEON, Suwon-si (KR); Jaesoon LIM, Suwon-si (KR); Hanjin LIM, Suwon-si (KR); Hyungsuk JUNG, Suwon-si (KR)

(73) Assignee: Samsung Electronics Co., Ltd., Suwon-si (KR)

(21) Appl. No.: 18/474,072

(22) Filed: Sep. 25, 2023

(30) Foreign Application Priority Data
Nov. 14, 2022 (KR) 10-2022-0152049

(51) Int. Cl. H10B 12/00

(52) U.S. Cl. CPC H01L 28/90; H10B 12/315; H10B 12/482; H10B 12/488

(57) ABSTRACT

A semiconductor device may include a substrate; a plurality of lower electrodes on the substrate; at least one supporter layer in contact with the plurality of lower electrodes; a dielectric layer on the plurality of lower electrodes and the at least one supporter layer; and an upper electrode on the dielectric layer. Each of the plurality of lower electrodes may include a first lower electrode and a second lower electrode on the first lower electrode. The at least one supporter layer may include a first supporter layer in contact with a side surface of an upper region of the first lower electrode. A level of an uppermost end of the second lower electrode may be higher than a level of an upper surface of the first supporter layer.

### CROSS-REFERENCE TO RELATED APPLICATION(S)

This application claims benefit of priority to Korean Patent Application No. 10-2022-0152049 filed on Nov. 14, 2022 in the Korean Intellectual Property Office, the disclosure of which is incorporated herein by reference in its entirety.

### BACKGROUND

Example embodiments of the present disclosure relate to a semiconductor device.

In response to demands for high integration density and miniaturization of a semiconductor device, a size of capacitor in a semiconductor device has also been miniaturized. Accordingly, various studies have been conducted to optimize a structure of a capacitor for storing data in a dynamic random-access memory (DRAM).

### SUMMARY

An example embodiment of the present disclosure provides a semiconductor device having improved electrical properties and reliability.

According to an example embodiment of the present disclosure, a semiconductor device may include a substrate; a plurality of lower electrodes on the substrate; at least one supporter layer in contact with the plurality of lower electrodes; a dielectric layer on the plurality of lower electrodes and the at least one supporter layer; and an upper electrode on the dielectric layer. Each of the plurality of lower electrodes may include a first lower electrode and a second lower electrode on the first lower electrode. The at least one supporter layer may include a first supporter layer in contact with a side surface of an upper region of the first lower electrode. A level of an uppermost end of the second lower electrode may be higher than a level of an upper surface of the first supporter layer.

According to an example embodiment of the present disclosure, a semiconductor device may include a substrate; a plurality of lower electrodes on the substrate; at least one supporter layer in contact with the plurality of lower electrodes; a dielectric layer on the plurality of lower electrodes; and an upper electrode on the dielectric layer. The plurality of lower electrodes may include a first lower electrode and a second lower electrode. The second lower electrode may be in contact with an upper surface of the first lower electrode. The at least one supporter layer may include a first supporter layer in contact with a side surface of an upper region of the first lower electrode. An upper surface of the first supporter layer and an upper surface of the first lower electrode may be substantially coplanar with each other. A level of an uppermost end of the second lower electrode may be higher than a level of an upper surface of the first lower electrode.

According to an example embodiment of the present disclosure, a semiconductor device may include a substrate; a device isolation layer on the substrate, the device isolation layer defining active regions on the substrate, the active regions including first impurity regions and second impurity regions in the active regions; gate electrodes intersecting the active regions and extending into the device isolation layer, the gate electrodes disposed such that the first impurity regions and the second impurity regions in the active regions are on both sides of the gate electrodes, respectively; bit lines on the gate electrodes, the bit lines being electrically connected to the first impurity regions; upper conductive patterns on side surfaces of the bit lines and electrically connected to the second impurity regions; lower electrodes extending vertically on the upper conductive patterns and connected to the upper conductive patterns, the lower electrodes including a first electrode pattern and a second electrode pattern adjacent to each other; at least one supporter layer between the first electrode pattern and the second electrode pattern and in contact with the first electrode pattern and the second electrode pattern; an upper electrode on the lower electrodes; and a dielectric layer between the lower electrodes and the upper electrode. The at least one supporter layer may include a first supporter layer and a second supporter layer on the first supporter layer. Each of the first electrode pattern and the second electrode pattern may include a first lower electrode and a second lower electrode on the first lower electrode. A level of an uppermost end of the second lower electrode may be higher than a level of an upper surface of the second supporter layer. The second lower electrode may cover at least a portion of the upper surface of the first lower electrode.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to an example embodiment of the present disclosure;

FIG. 2 is a cross-sectional diagram illustrating a semiconductor device according to an example embodiment of the present disclosure;

FIGS. 3, 4, 5, 6, 7, 8, 9, and 10 are enlarged cross-sectional diagrams illustrating a region including a capacitor of a semiconductor device according to an example embodiment of the present disclosure; and

FIGS. 11A, 11B, 11C, 11D, 11E, and 11F are cross-sectional diagrams illustrating a method of manufacturing a semiconductor device according to an example embodiment of the present disclosure.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, embodiments of the present disclosure will be described as follows with reference to the accompanying drawings.

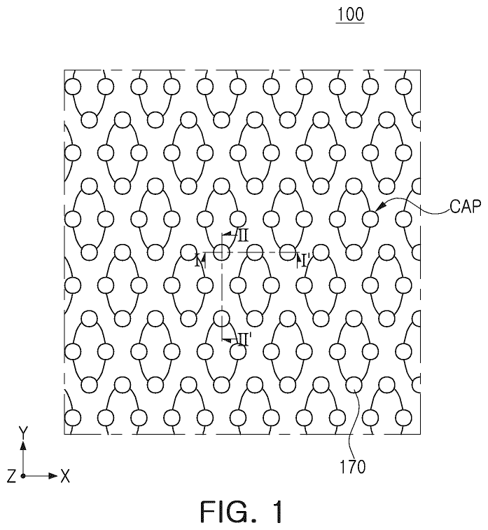

FIG. 1 is a plan diagram illustrating a semiconductor device according to an example embodiment.

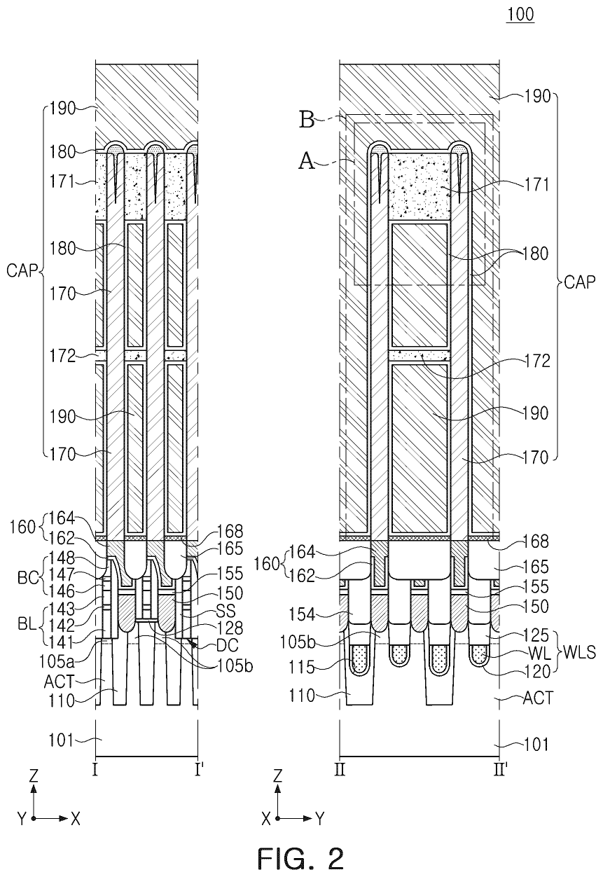

FIG. 2 is a cross-sectional diagram illustrating a semiconductor device according to an example embodiment, taken along lines I-I′ and II-II′ in FIG. 1.

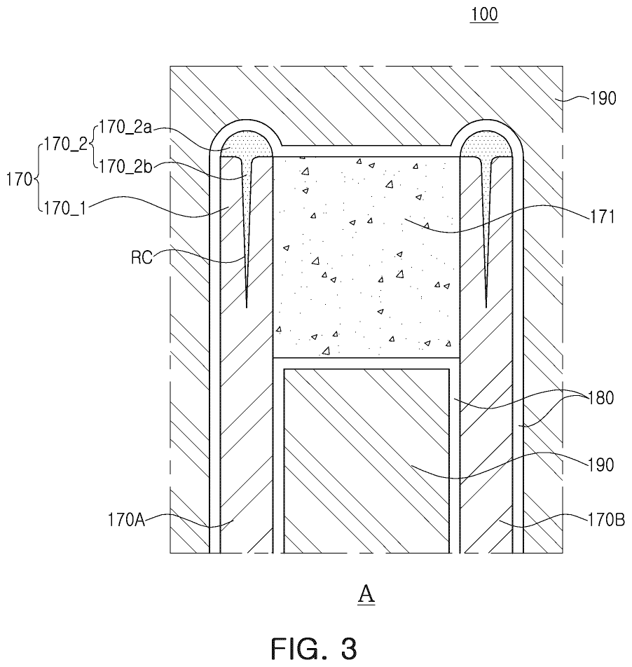

FIGS. 3 to 10 are enlarged cross-sectional diagrams illustrating a region including a capacitor of a semiconductor device according to an example embodiment, illustrating region “A” in FIG. 2.

Referring to FIGS. 1 to 3, the semiconductor device 100 may include a substrate 101 including active regions ACT, a device isolation layer 110 defining active regions ACT within the substrate 101, a word line structure WLS extending by being embedded in the substrate 101 and including a word line WL, a bit line structure BLS extending by intersecting the word line structure WLS on the substrate 101 and including a bit line BL, and a capacitor structure CAP on the bit line structure BLS. The semiconductor device 100 may further include a lower conductive pattern 150 on the active region ACT, an upper conductive pattern 160 on the lower conductive pattern 150, and an insulating pattern 165 penetrating the upper conductive pattern 160.

The semiconductor device 100 may include, for example, a dynamic random access memory DRAM cell array. For example, the bit line BL may be connected to the first impurity region 105a of the active region ACT, and the second impurity region 105b of the active region ACT may be electrically connected to the capacitor structure CAP on the upper conductive pattern 160 through the lower and upper conductive patterns 150 and 160. The capacitor structure CAP may include lower electrodes 170, a dielectric layer 180 on the lower electrodes 170, and an upper electrode 190 on the dielectric layer 180. The capacitor structure CAP may further include an etch stop layer 168 and supporter layers 171 and 172.

The semiconductor device 100 may include a cell array region in which a cell array is disposed and a peripheral circuit region in which peripheral circuits for driving memory cells disposed in the cell array are disposed. The peripheral circuit region may be disposed around the cell array region.

The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may include a silicon substrate, a silicon on insulator SOI substrate, a germanium substrate, a germanium on insulator GOI substrate, a silicon-germanium substrate, or a substrate including an epitaxial layer.

The active regions ACT may be defined within the substrate 101 by the device isolation layer 110. The active region ACT may have a bar shape and may be disposed in an island shape extending in one direction within the substrate 101. The one direction may be a direction inclined with respect to an extension direction of the word lines WL and the bit lines BL. The active regions ACT may be arranged in parallel to each other, and an end of one active region ACT may be arranged to be adjacent to a center of another active region ACT adjacent thereto.

The active region ACT may have first and second impurity regions 105a and 105b at a desired and/or predetermined depth from the upper surface of the substrate 101. The first and second impurity regions 105a and 105b may be spaced apart from each other. The first and second impurity regions 105a and 105b may be provided as source/drain regions of transistors formed by the word line WL. The source region and the drain region may be formed by first and second impurity regions 105a and 105b by doping substantially the same impurities or ion implantation, and may be referred to interchangeably depending on the circuit configuration of a finally formed transistor. The impurities may include dopants having conductivity opposite to that of the substrate 101. In example embodiments, depths of the first and second impurity regions 105a and 105b in the source region and the drain region may be different. The device isolation layer 110 may be formed by a shallow trench isolation (STI) process. The device isolation layer 110 may surround the active regions ACT and may electrically isolate the active regions ACT from each other. The device isolation layer 110 may be formed of an insulating material, for example, silicon oxide, silicon nitride, or a combination thereof. The device isolation layer 110 may include a plurality of regions having different lower end depths depending on a width of the trench in which the substrate 101 is etched.

Word line structures WLS may be disposed in the gate trenches 115 extending within the substrate 101. Each of the word line structures WLS may include a gate dielectric layer 120, a word line WL, and a gate capping layer 125. In example embodiments, the “gate 120 WL” may be referred to as a structure including the gate dielectric layer 120 and the word line WL, the word line WL may be referred to as a “gate electrode,” and the word line structure WLS may be referred to as a “gate structure.”

The word line WL may be disposed to intersect the active region ACT and to extend in the first direction X. For example, a pair of adjacent word lines WL may be arranged to intersect one active region ACT. The word line WL may be included in a gate of a buried channel array transistor BCAT, but an example embodiment thereof is not limited thereto. In example embodiments, the word lines WL may also be configured to be disposed on the substrate 101. The word line WL may be disposed below the gate trench 115 to have a desired and/or predetermined thickness. An upper surface of the word line WL may be disposed on a level lower than a level of an upper surface of the substrate 101. In example embodiments, high or low “level” may be defined based on a substantially flat upper surface of the substrate 101.

The word line WL may include a conductive material, and, for example, may at least one of polycrystalline silicon (Si), titanium (Ti), titanium nitride (TiN), tantalum (Ta), tantalum nitride (TaN), tungsten (W), tungsten nitride (WN) and aluminum (Al). For example, the word line WL may include a lower pattern and an upper pattern formed of different materials, the lower pattern may include at least one of tungsten (W), titanium (Ti), tantalum (Ta), tungsten nitride (WN), titanium nitride (TiN), and tantalum nitride (TaN), and the upper pattern may be a semiconductor pattern including polysilicon doped with P-type or N-type impurities.

The gate dielectric layer 120 may be disposed on the bottom surface and internal side surfaces of the gate trench 115. The gate dielectric layer 120 may conformally cover the internal sidewall of the gate trench 115. The gate dielectric layer 120 may include at least one of silicon oxide, silicon nitride, and silicon oxynitride. The gate dielectric layer 120 may be, for example, a silicon oxide film or an insulating film having a high dielectric constant. In example embodiments, the gate dielectric layer 120 may be a layer formed by oxidizing an active region ACT or a layer formed by deposition.

The gate capping layer 125 may be disposed to fill the gate trench 115 above the word line WL. An upper surface of the gate capping layer 125 may be disposed on substantially the same level as a level of an upper surface of the substrate 101. The gate capping layer 125 may be formed of an insulating material, for example, silicon nitride.

The bit line structure BLS may extend in one direction perpendicular to the word line WL, for example, in a second direction Y. The bit line structure BLS may include a bit line BL and a bit line capping pattern BC on the bit line BL.

The bit line BL may include a first conductive pattern 141, a second conductive pattern 142, and a third conductive pattern 143 stacked in order. The bit line capping pattern BC may be disposed on the third conductive pattern 143. A buffer insulating layer 128 may be disposed between the first conductive pattern 141 and the substrate 101, and a portion of the first conductive pattern 141 (hereinafter, a bit line contact pattern DC) may be in contact with the first impurity region 105a of the active region ACT. The bit line BL may be electrically connected to the first impurity region 105a through the bit line contact pattern DC. The lower surface of the bit line contact pattern DC may be disposed on a level lower than a level of the upper surface of the substrate 101 and may be disposed on a level higher than a level of the upper surface of the word line WL. In an example embodiment, a bit line contact pattern DC may be formed in the substrate 101 and may be locally disposed in a bit line contact hole exposing the first impurity region 105a.

The first conductive pattern 141 may include a semiconductor material such as polycrystalline silicon. The first conductive pattern 141 may be in direct contact with the first impurity region 105a. The second conductive pattern 142 may include a metal-semiconductor compound. The metal-semiconductor compound may be, for example, a layer in which a portion of the first conductive pattern 141 is silicided. For example, the metal-semiconductor compound may include cobalt silicide (CoSi), titanium silicide (TiSi), nickel silicide (NiSi), tungsten silicide (WSi), or other metal silicides. The third conductive pattern 143 may include a metal material such as titanium (Ti), tantalum (Ta), tungsten (W), and aluminum (Al). The number of conductive patterns included in the bit line BL, the type of material, and/or the stacking order may be varied in example embodiments.

The bit line capping pattern BC may include a first capping pattern 146, a second capping pattern 147, and a third capping pattern 148 stacked in order on the third conductive pattern 143. Each of the first to third capping patterns 146, 147, and 148 may include an insulating material, for example, a silicon nitride layer. The first to third capping patterns 146, 147, and 148 may be formed of different materials, and even when the patterns include the same material, a boundary may be distinct due to a difference in physical properties. A thickness of the second capping pattern 147 may be smaller than a thickness of the first capping pattern 146 and a thickness of the third capping pattern 148. The number of capping patterns included in the bit line capping pattern BC and/or the type of material thereof may be varied in example embodiments.

The spacer structure SS may be disposed on both sidewalls of each of the bit line structures BLS and may extend in one direction, for example, the Y-direction. The spacer structure SS may be disposed between the bit line structure BLS and the lower conductive pattern 150. The spacer structure SS may be disposed to extend along sidewalls of the bit line BL and sidewalls of the bit line capping pattern BC. A pair of spacer structures SS disposed on both sides of one bit line structure BLS may have an asymmetrical shape with respect to the bit line structure BLS. Each of the spacer structures SS may include a plurality of spacer layers, and may further include air spacers in example embodiments.

The lower conductive pattern 150 may be connected to one region of the active region ACT, for example, the second impurity region 105b. The lower conductive pattern 150 may be disposed between the bit lines BL and between the word lines WL. The lower conductive pattern 150 may penetrate through the buffer insulating layer 128 and may be connected to the second impurity region 105b of the active region ACT. The lower conductive pattern 150 may be in direct contact with the second impurity region 105b. The lower surface of the lower conductive pattern 150 may be disposed on a level lower than a level of the upper surface of the substrate 101 and may be disposed on a level higher than a level of the lower surface of the bit line contact pattern DC. The lower conductive pattern 150 may be insulated from the bit line contact pattern DC by the spacer structure SS. The lower conductive pattern 150 may be formed of a conductive material, for example, at least one of polycrystalline silicon (Si), titanium (Ti), titanium nitride (TiN), tantalum (Ta), tantalum nitride (TaN), tungsten (W), tungsten nitride (WN), and aluminum (Al). In an example embodiment, the lower conductive pattern 150 may include a plurality of layers.

A metal-semiconductor compound layer 155 may be disposed between the lower conductive pattern 150 and the upper conductive pattern 160. The metal-semiconductor compound layer 155 may be obtained by, for example, siliciding a portion of the lower conductive pattern 150 when the lower conductive pattern 150 includes a semiconductor material. The metal-semiconductor compound layer 155 may include, for example, cobalt silicide (CoSi), titanium silicide (TiSi), nickel silicide (NiSi), tungsten silicide (WSi), or other metal silicide. In example embodiments, the metal-semiconductor compound layer 155 may not be provided.

The upper conductive pattern 160 may be disposed on the lower conductive pattern 150. The upper conductive pattern 160 may extend to a region between the spacer structures SS and may cover the upper surface of the metal-semiconductor compound layer 155. The upper conductive pattern 160 may include a barrier layer 162 and a conductive layer 164. The barrier layer 162 may cover the lower surface and side surfaces of the conductive layer 164. The barrier layer 162 may include at least one of a metal nitride, such as titanium nitride (TiN), tantalum nitride (TaN), and tungsten nitride (WN). The conductive layer 164 may include a conductive material, for example, at least one of polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), and tungsten nitride (WN).

The insulating patterns 165 may be disposed to penetrate through the upper conductive pattern 160. The upper conductive patterns 160 may be divided into a plurality of insulating patterns 165 by the insulating patterns 165. The insulating patterns 165 may include an insulating material, for example, at least one of silicon oxide, silicon nitride, and silicon oxynitride.

The capacitor structure CAP will be described in greater detail with reference to FIG. 3 below.

The etch stop layer 168 may cover the insulating patterns 165 between the lower electrodes 170. The etch stop layer 168 may be in contact with the lower region of the side surfaces of the lower electrodes 170. The etch stop layer 168 may be disposed below the supporter layers 171 and 172. An upper surface of the etch stop layer 168 may include a portion in direct contact with the dielectric layer 180. The etch stop layer 168 may include, for example, at least one of silicon nitride and silicon oxynitride.

Each of the lower electrodes 170 may include a first lower electrode 170_1 and a second lower electrode 170_2 in contact with the upper surface of the first lower electrode 170_1. The lower electrodes 170 may be disposed on the upper conductive patterns 160. The lower electrodes 170 may penetrate through the etch stop layer 168 and may be in contact with the upper conductive patterns 160.

Each of the lower electrodes 170 may have a cylindrical shape or an upper region thereof may have a hollow cylindrical shape or a cup shape. For example, the first lower electrode 170_1 may have a cylindrical shape or an upper region thereof may have a hollow cylindrical shape or a cup shape, and the second lower electrodes 170_2 may have a dome structure covering at least a portion of the first lower electrode 170_1. An upper surface of the second lower electrode 170_2 may have a rounded shape. The second lower electrode 170_2 may be formed on the first lower electrode 170_1 using an area selective atomic layer deposition process. Since the second lower electrode 170_2 covers at least a portion of the first lower electrode 170_1, the upper surface of the first lower electrode 170_1 may be spaced apart from the dielectric layer 180 by the second lower electrode 170_2. In an example embodiment, the second lower electrode 170_2 may protrude in the direction opposite to the substrate 101, and the uppermost end of the second lower electrodes 170_2 may be disposed on a level higher than a level of the upper surface of the first supporter layer 171. Also, the uppermost end of the second lower electrode 170_2 may be disposed on a level higher than a level of the upper surface of the first lower electrode 170_1. Since the second lower electrode 170_2 protrudes to be disposed on a level higher than a level of the upper surface of the first supporter layer 171, the area of the lower electrodes 170 may increase, thereby increasing capacitance of the capacitor structure CAP.

According to an example embodiment, the first lower electrode 170_1 may have a recess region RC extending in a downward direction from the central region of the upper surface of the first lower electrode 170_1. At least a portion of the recess region RC may have a shape of which a width may decrease downwardly, but an example embodiment thereof is not limited thereto. The second lower electrode 170_2 may include a first portion 170_2b filling at least a portion of the recess region RC and a second portion 170_2a extending from the first portion 170_2b and covering the upper surface of the first lower electrode 170_1. For example, the first portion 170_2b may fill the entire recess region RC, but an example embodiment thereof is not limited thereto. According to an example embodiment, the lower end of the first portion 170_2b may be disposed on a level higher than a level of the lower surface of the first supporter layer 171 and may be disposed on a level lower than a level of the upper surface of the first supporter layer 171, but an example embodiment thereof is not limited thereto.

The lowermost end of the second lower electrode 170_2 may be disposed on a level lower than a level of the upper surface of the first lower electrode 170_1, but an example embodiment thereof is not limited thereto. The lowermost end of the second lower electrode 170_2 may be disposed on a level higher than a level of the lower surface of the first supporter layer 171, but an example embodiment thereof is not limited thereto. According to an example embodiment, at least a portion of surfaces in contact with the first lower electrode 170_1 and the second lower electrode 170_2 may be coplanar with the upper surface of the first supporter layer 171. That is, at least a portion of the upper surface of the first lower electrode 170_1 and at least a portion of the lower surface of the second lower electrode 170_2 may be coplanar with the upper surface of the first supporter layer 171.

At least one supporter layer 171 and 172 for supporting the lower electrodes 170 may be provided between lower electrodes 170 adjacent to each other. For example, as illustrated in FIG. 3, a first supporter layer 171 and a second supporter layer 172 in contact with the first electrode pattern 170A and the second electrode pattern 170B may be provided between the first electrode pattern 170A and the second electrode pattern 170B adjacent to each other among the lower electrodes 170. The lower electrodes 170 may include at least one of niobium nitride (NbN), niobium oxide (NbOx), polycrystalline silicon (Si), iridium (Jr), titanium (Ti), titanium nitride (TiN), titanium silicide nitride (TiSiN), and tantalum (Ta), tantalum nitride (TaN), tungsten (W), tungsten nitride (WN), and aluminum (Al) or a combination thereof, and a metal nitride, a metal compound. According to an example embodiment, the first lower electrode 170_1 and the second lower electrode 170_2 may be formed of substantially the same material, but an example embodiment thereof is not limited thereto. For example, the first lower electrode 170_1 and the second lower electrode 170_2 may include titanium nitride (TiN). According to another example embodiment, the first lower electrode 170_1 and the second lower electrode 170_2 may include different materials. For example, the first lower electrode 170_1 may include titanium nitride (TiN), and the second lower electrode 170_2 may include niobium nitride (NbN).

The supporter layers 171 and 172 may include the first supporter layer 171 in contact with the side surface of the upper region of the first lower electrode 170_1 and the second supporter layer 172 on a level lower than a level of the first supporter layer 171. The supporter layers 171 and 172 may be in contact with the lower electrodes 170 and may extend in a direction parallel to the upper surface of the substrate 101. The first supporter layer 171 may have a thickness greater than that of the second supporter layer 172, but an example embodiment thereof is not limited thereto. The supporter layers 171 and 172 may support the lower electrodes 170 having a high aspect ratio. Each of the supporter layers 171 and 172 may include, for example, at least one of silicon nitride and silicon oxynitride, or a material similar thereto. The number, thickness, and/or arrangement relationship of the supporter layers 171 and 172 are not limited to illustrated examples and may be varied in example embodiments.

The dielectric layer 180 may cover the etch stop layer 168, the lower electrodes 170, and the supporter layers 171 and 172. The dielectric layer 180 may conformally cover the upper and side surfaces of the lower electrodes 170, the upper surface of the etch stop layer 168, and exposed surfaces of the supporter layers 171 and 172. In an example embodiment, the dielectric layer 180 may surround the upper surface of the second lower electrode 170_2. The dielectric layer 180 may extend to a region between the upper electrode 190 and the supporter layers 171 and 172. In example embodiments, upper and lower surfaces of each of the supporter layers 171 and 172 may be in contact with the dielectric layer 180. The dielectric layer 180 may extend to a region between the upper electrode 190 and the etch stop layer 168. In example embodiments, an upper surface of the etch stop layer 168 may be in contact with the dielectric layer 180. The dielectric layer 180 may include a high dielectric material, silicon oxide, silicon nitride, silicon oxynitride, or a combination thereof. However, in example embodiments, the dielectric layer 180 may include oxide, nitride, silicide, oxynitride, or silicified oxynitride including at least one of titanium (Ti), tantalum (Ta), hafnium (Hf), aluminum (Al), zirconium (Zr), and lanthanum (La) or a combination thereof.

The upper electrode 190 may be disposed on the dielectric layer 180. The upper electrode 190 may extend along the surface of the dielectric layer 180. The upper electrode 190 may be disposed on the lower electrodes 170 and the supporter layers 171 and 172. The upper electrode 190 may cover the dielectric layer 180 between the lower electrodes 170 and may be disposed to fill a space between the lower electrodes 170. The upper electrode 190 may include at least one of niobium nitride (NbN), niobium oxide (NbOx), polycrystalline silicon (Si), iridium (Jr), titanium (Ti), titanium nitride (TiN), titanium silicide nitride (TiSiN), tantalum (Ta), tantalum nitride (TaN), tungsten (W), tungsten nitride (WN), aluminum (Al) or a combination thereof, a metal nitride, and a metal compound.

In the description of the embodiments below, descriptions overlapping the descriptions described above with reference to FIGS. 1 to 3 will not be provided.

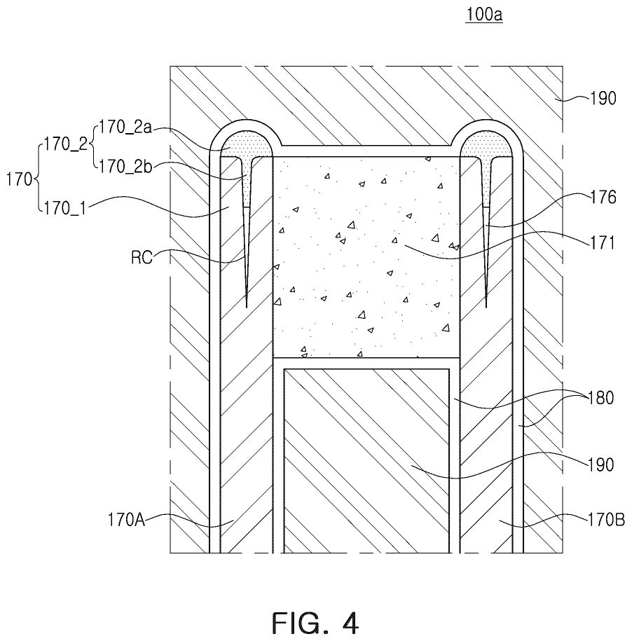

FIGS. 4 to 10 are enlarged cross-sectional diagrams illustrating a region including a capacitor of a semiconductor device according to an example embodiment, illustrating a region corresponding to region “A” in FIG. 2.

Referring to FIG. 4, the semiconductor device 100a may further include a void 176. The second lower electrode 170_2 may include a first portion 170_2b partially filling the recess region RC and a second portion 170_2a extending from the first portion 170_2b and covering the upper surface of the first lower electrode 170_1. A portion not filled in the first portion 170_2b of the second lower electrode 170_2 in the recess region RC may be defined as a void 176. The void 176 may be formed during an atomic layer distribution ALD process of the second lower electrode 170_2. The void 176 may include air or a gas formed of a material used in a process of manufacturing the semiconductor device 100a. The void 176 may be formed by partially filling the recess region RC with the first portion 170_2b. The void 176 may be disposed between the first portion 170_2b of the second lower electrode 170_2 and the lower end of the recess region RC. That is, the void 176 may be defined by the first lower electrode 170_1 and the second lower electrode 170_2. In an example embodiment, the lowermost end of the second lower electrode 170_2 may be disposed on a level lower than a level of the upper surface of the first supporter layer 171. An uppermost end of the void 176 may be disposed on a level lower than a level of the upper surface of the first supporter layer 171.

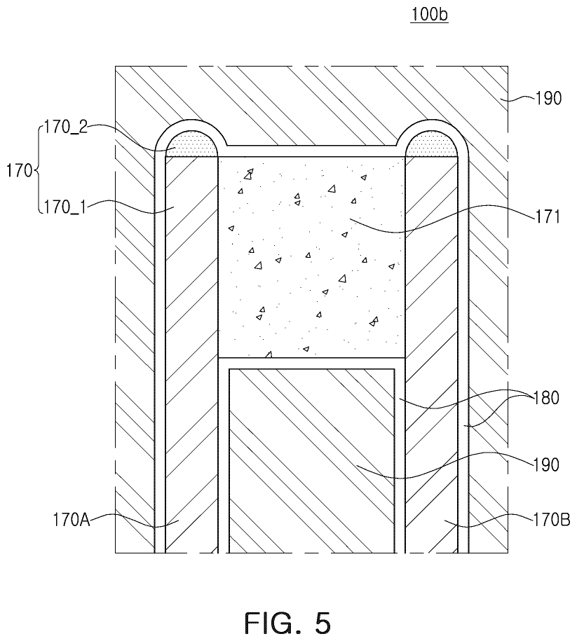

Referring to FIG. 5, in the semiconductor device 100b, an upper surface of the first lower electrode 170_1 may be substantially flat. An upper surface of the first supporter layer 171 and an upper surface of the first lower electrode 170_1 may be substantially coplanar with each other. In an example embodiment, the lower surface of the second lower electrode 170_2 may be parallel to the upper surface of the second supporter layer 172. A portion of the upper surface of the first lower electrode 170_1 and the lower surface of the second lower electrode 170_2 may be coplanar with the upper surface of the second supporter layer 172.

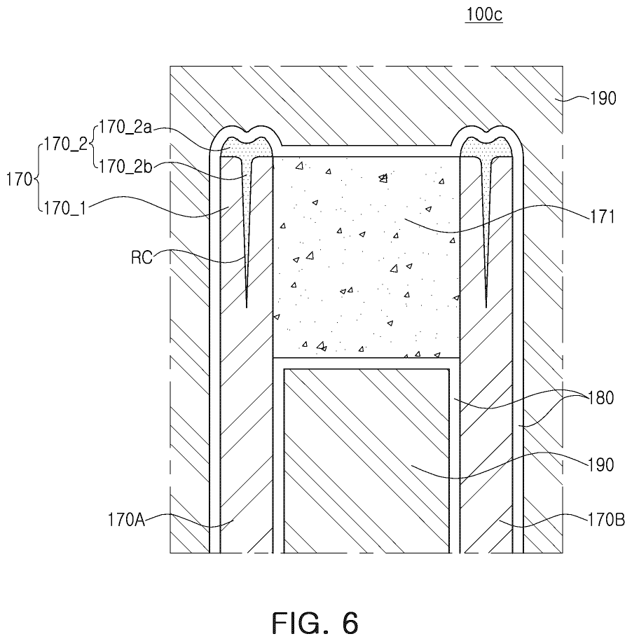

Referring to FIG. 6, in the semiconductor device 100c, an upper surface of the second lower electrode 170_2 may have a wavy shape. The second lower electrode 170_2 may be formed on the first lower electrode 170_1 using an area selective atomic layer deposition process. In an example embodiment, an upper surface of the second lower electrode 170_2 may have a curved shape from a central axis area of the second lower electrode 170_2 toward the first lower electrode 170_1. The lowermost end of the second lower electrode 170_2 may be disposed on a level higher than a level of the lower surface of the first supporter layer 171, but an example embodiment thereof is not limited thereto, and the lowermost end of the second lower electrode 170_2 may be disposed on substantially the same level as or a level lower than a level of the lower surface of the second supporter layer 172.

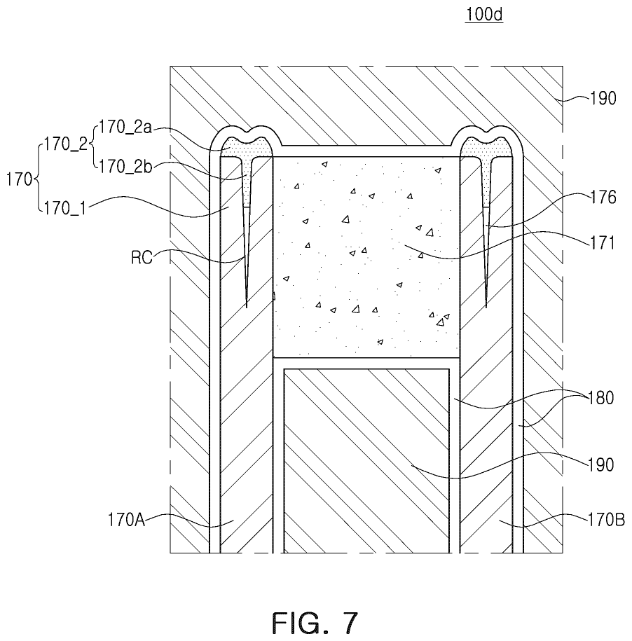

Referring to FIG. 7, the semiconductor device 100c may further include a void 176 between the first lower electrode 170_1 and the second lower electrode 170_2. An upper surface of the second lower electrode 170_2 may have a wavy shape. The second lower electrode 170_2 may fill a portion of the recess region RC. According to an example embodiment, the lowermost end of the second lower electrode 170_2 may be disposed on a level lower than a level of the upper surface of the first supporter layer 171. An uppermost end of the void 176 may be disposed on a level lower than a level of the upper surface of the first supporter layer 171.

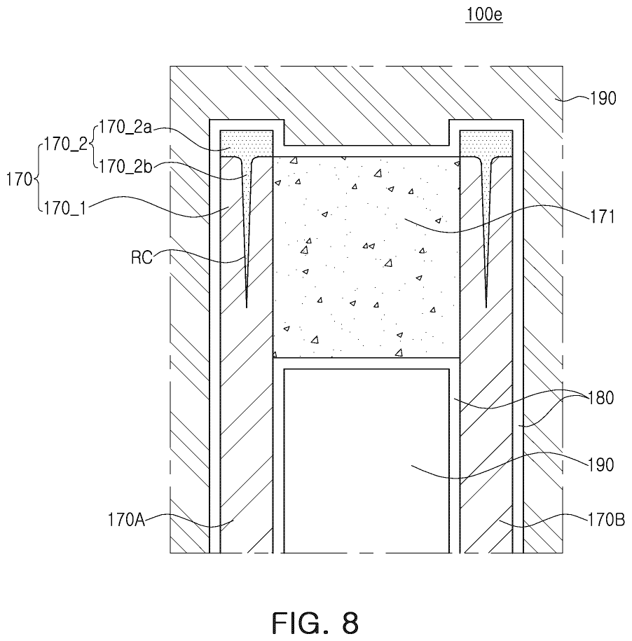

Referring to FIG. 8, in the semiconductor device 100e, an upper portion of the second lower electrode 170_2 may have a rectangular shape. In an example embodiment, the upper surface of the second lower electrode 170_2 may be parallel to the upper surface of the substrate 101. For example, the upper surface of the second lower electrode 170_2 may be parallel to the upper surface of the first supporter layer 171.

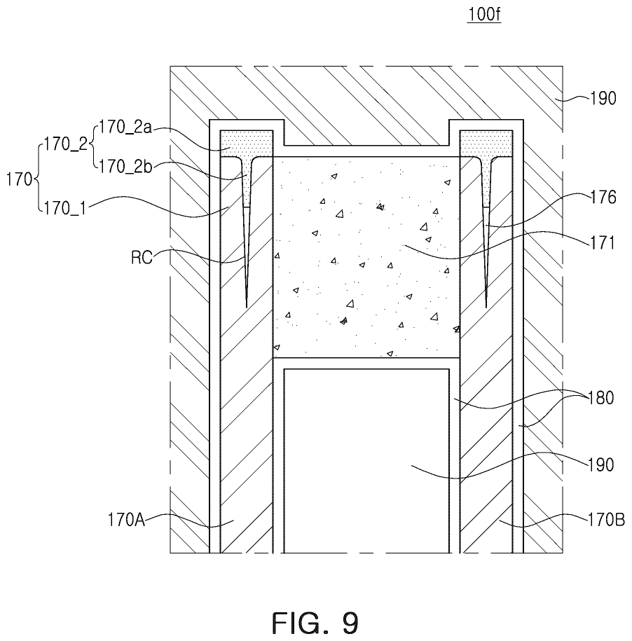

Referring to FIG. 9, the semiconductor device 100f may further include a void 176 between the first lower electrode 170_1 and the second lower electrode 170_2. The void 176 in FIG. 9 may have substantially the same characteristics as those of the void 176 in FIG. 4 described above.

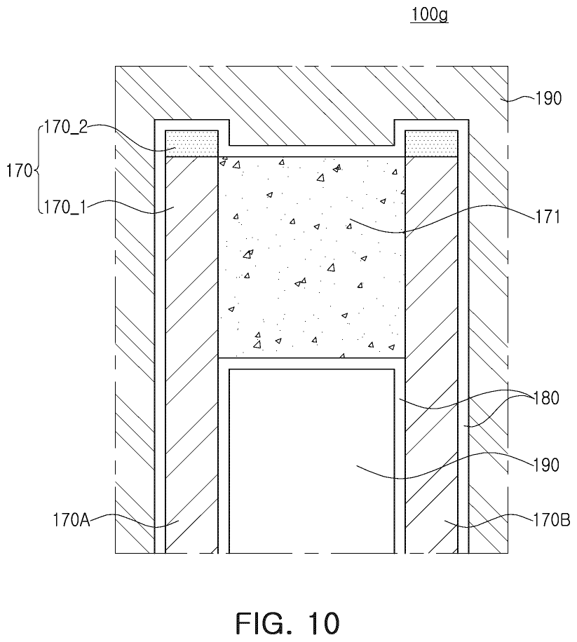

Referring to FIG. 10, in the semiconductor device 100g, a seam may not be formed according to a process, and the upper surface of the first supporter layer 171 and the upper surface of the first lower electrode 170_1 may be substantially coplanar with each other. In an example embodiment, the lower surface of the second lower electrode 170_2 may be substantially coplanar with the upper surface of the first lower electrode 170_1 and the upper surface of the first supporter layer 171.

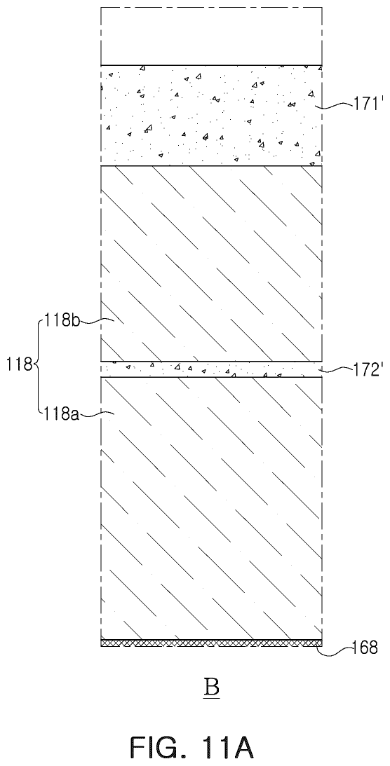

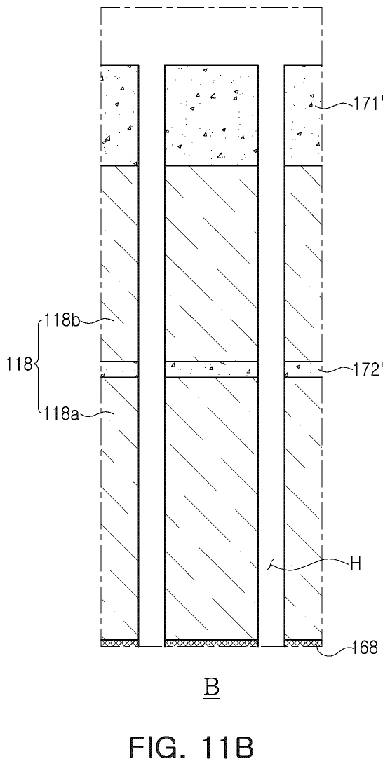

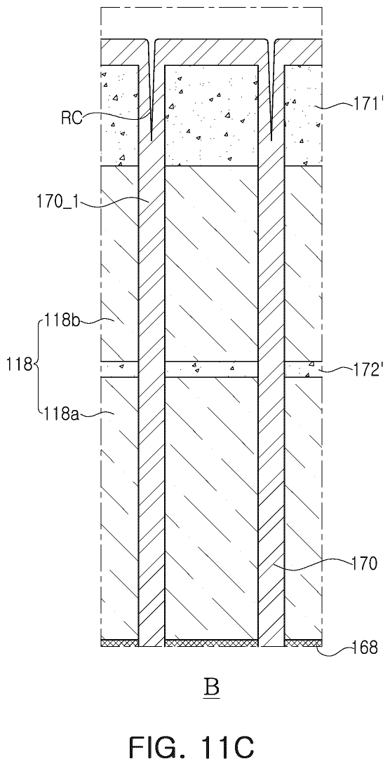

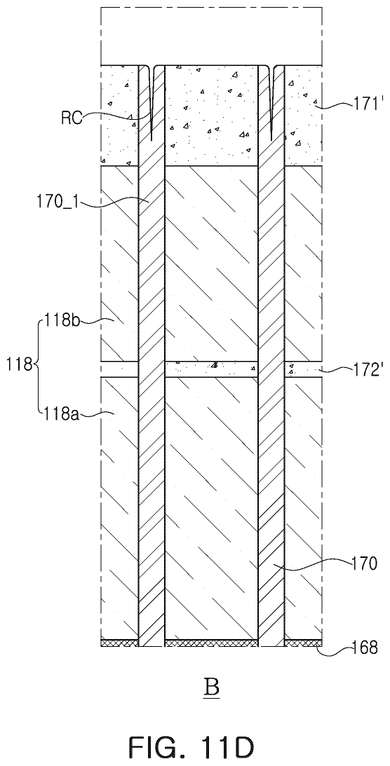

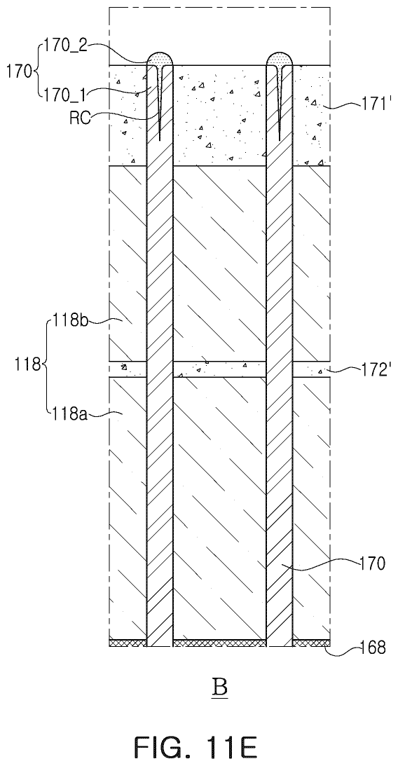

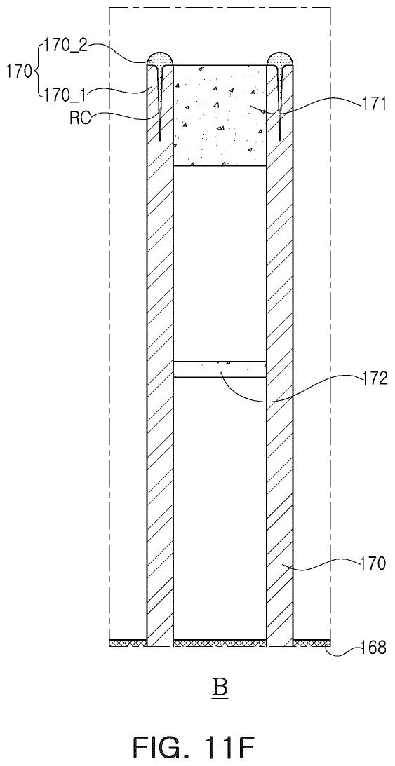

FIGS. 11A to 11F are cross-sectional diagrams illustrating a method of manufacturing a semiconductor device according to an example embodiment, illustrating a process of forming a capacitor structure disposed in “B” region in FIG. 2.

Referring to FIG. 2, an active region ACT may be defined by forming a device isolation layer 110 on a substrate 101. A device isolation trench may be formed in the substrate 101, and the device isolation layer 110 may fill the device isolation trench. On a plane, the active region ACT may have a shape of an elongated bar extending in a direction oblique to the extension direction of the word line WL. An ion implantation process may be performed using the device isolation layer 110 as an ion implantation mask, thereby forming impurity regions on the active region ACT. A gate trench 115 may be formed by patterning the active region ACT and the device isolation layer 110. A pair of gate trenches 115 may intersect the active region ACT, but an example embodiment thereof is not limited thereto. The impurity regions may also be isolated from each other by the gate trench 115, thereby forming a first impurity region 105a and a second impurity region 105b.

The gate dielectric layer 120 may be formed on the inner surface of the gate trench 115 to a substantially conformal thickness. Thereafter, the word line WL may be formed to fill at least a portion of the gate trench 115. An upper surface of the word line WL may be recessed to be on a level lower than a level of an upper surface of the active region ACT. The gate trench 115 may be filled by stacking an insulating layer on the substrate 101, and may be etched to form a gate capping layer 125 on the word line WL.

An insulating layer and a conductive layer may be formed in order on the entire surface of the substrate 101 and may be patterned to form a buffer insulating layer 128 and a first conductive pattern 141 stacked in order. The buffer insulating layer 128 may be formed of at least one of silicon oxide, silicon nitride, and silicon oxynitride. A plurality of buffer insulating layers 128 may be spaced apart from each other. The first conductive pattern 141 may have a shape corresponding to the planar shape of the buffer insulating layer 128. The buffer insulating layer 128 may be formed to simultaneously cover ends of two adjacent active regions ACT, that is, the second impurity regions 105b adjacent to each other. A bit line contact hole may be formed by etching the upper portions of the device isolation layer 110, the substrate 101, and the gate capping layer 125 using the buffer insulating layer 128 and the first conductive pattern 141 as etch masks. The bit line contact hole may expose the first impurity region 105a.

A bit line contact pattern DC filling a bit line contact hole may be formed. The forming the bit line contact pattern DC may include forming a conductive layer filling the bit line contact hole and performing a planarization process. For example, the bit line contact pattern DC may be formed of polysilicon. The second conductive pattern 142, the third conductive pattern 143, and the first to third capping patterns 146, 147, and 148 may be formed in order on the first conductive pattern 141, and the first to third conductive patterns 141, 142, and 143 may be etched in order using the first to third capping patterns 146, 147, and 148 as etch masks. Accordingly, a bit line structure BLS including the bit line BL including the first to third conductive patterns 141, 142, and 143 and the bit line capping pattern BC including the first to third capping patterns 146, 147, and 147 may be formed.

A spacer structure SS may be formed on side surfaces of the bit line structure BLS. The spacer structure SS may include a plurality of layers. Fence insulating patterns 154 may be formed between the spacer structure SS. The fence insulating patterns 154 may include silicon nitride or silicon oxynitride. An opening exposing the second impurity region 105b may be formed by performing an anisotropic etching process using the fence insulating patterns 154 and the third capping pattern 148 as etching masks.

A lower conductive pattern 150 may be formed below the opening. The lower conductive pattern 150 may be formed of a conductor material such as polysilicon. For example, the lower conductive pattern 150 may be formed by forming a polysilicon layer filling the opening and performing an etch-back process.

A metal-semiconductor compound layer 155 may be formed on the lower conductive pattern 150. The forming the metal-semiconductor compound layer 155 may include a metal layer deposition process and a heat treatment process.

An upper conductive pattern 160 may be formed on the first opening. The forming the upper conductive pattern 160 may include forming the barrier layer 162 and the conductive layer 164 in order. Thereafter, insulating patterns 165 may be formed by performing a patterning process on the barrier layer 162 and the conductive layer 164. Accordingly, a lower structure including the substrate 101, the word line structure WLS, and the bit line structure BLS may be formed.

Thereafter, referring to FIG. 11A, an etch stop layer 168 may be conformally formed on the lower structure, and mold layers 118 and preliminary supporter layers 171′, 172′ may be alternately stacked on the etch stop layer 168. The etch stop layer 168 may include an insulating material having etch selectivity with respect to the mold layers 118 under specific etching conditions, for example, at least one of silicon oxide, silicon nitride, silicon carbide, silicon oxycarbide, and silicon carbonitride. The mold layers 118 may include a first mold layer 118a and a second mold layer 118b on the first mold layer 118a. The first preliminary supporter layer 171′ may be formed on the second mold layer 118b, and the second preliminary supporter layer 172′ may be formed between the first mold layer 118a and the second mold layer 118b. For example, the mold layers 118 may be formed of silicon oxide and the preliminary supporter layers 171′ and 172′ may be formed of silicon nitride.

Referring to FIG. 11B, a plurality of holes H penetrating the mold layers 118 and preliminary supporter layers 171′ and 172′ may be formed. In the process of forming the plurality of holes H, the etch stop layer 168 may work as a stopper to stop the etching process. The plurality of holes H may penetrate the etch stop layer 168 and may expose the upper conductive patterns 160. The plurality of holes H may be regions in which the lower electrodes 170 may be formed, and as illustrated in FIG. 1, the plurality of holes H may be spaced apart from each other at desired and/or predetermined spacing on a plane and may be formed in a regular arrangement.

Referring to FIG. 11C, a first lower electrode 170_1 may be formed by filling the plurality of holes H with a conductive material. The first lower electrode 170_1 may be formed to be connected to the upper conductive pattern 160 on the lower end of the plurality of holes H. The first lower electrode 170_1 may be formed through an atomic layer deposition ALD process. The forming the first lower electrode 170_1 may include forming a conductive material layer in the plurality of holes H and on the plurality of holes H. The first lower electrode 170_1 may be formed to cover the preliminary supporter layers 171′ and 172′. Since the first lower electrode 170_1 has a high aspect ratio, a seam may be formed vertically along the central axis of the first lower electrode 170_1, but an example embodiment thereof is not limited thereto, and depending on the process method, a seam may not be formed and may not be formed along the central axis of the first lower electrode 170_1.

When a seam is formed vertically along the central axis of the first lower electrode 170_1, a gap or recess region RC may be formed in the upper region of the first lower electrode 170_1.

Referring to FIG. 11D, by partially removing the first lower electrode 170_1, nodes may be separated and a plurality of patterns spaced apart from each other may be formed. For example, the first lower electrode 170_1 covering the first preliminary supporter layer 171′ among the first lower electrodes 170_1 may be removed. A portion of the first lower electrode 170_1 may be removed using a dry etching or wet etching process. Also, a planarization process, for example, a chemical mechanical polishing CMP process may be performed on the first lower electrode 170_1. Accordingly, the first lower electrode 170_1 may be formed as a plurality of patterns spaced apart from each other by separating nodes.

Referring to FIG. 11E, a second lower electrode 170_2 may be formed on the first lower electrode 170_1 and the first lower electrode 170_1. The second lower electrode 170_2 may be formed on the first lower electrode 170_1 and the first lower electrode 170_1 using an area selective atomic layer deposition process. The second lower electrode 170_2 may not be deposited on the first preliminary supporter layer 171′ and may be selectively deposited only on the first lower electrode 170_1. While performing the selective atomic layer deposition process on the second lower electrode 170_2, a precursor including a metal compound and a reactive gas such as H₂, NH₃, N₂, or the like, may be supplied. In example embodiments, an inhibitor for suppressing deposition on the surface of the first preliminary supporter layer 171′ may be supplied together. The second lower electrode 170_2 may fill at least a portion of the recess region RC.

Referring to FIG. 11F, a separate mask may be formed on the second preliminary supporter layer 172′, and at least a portion of the mold layers 118 and the preliminary supporter layers 171′ and 172′ may be removed using the mask. Accordingly, the preliminary supporter layers 171′ and 172′ may be formed as supporter layers 171 and 172. The supporter layers 171 and 172 may be patterned according to the structure of the mask and may have a shape including a plurality of openings. The supporter layers 171 and 172 may connect the lower electrodes 170 adjacent to each other. The mold layers 118 may selectively be removed with respect to supporter layers 171 and 172. The mask may be removed after the mold layers 118 are etched or while the mold layers 118 are etched.

Thereafter, referring to FIGS. 3 and 11F together, a dielectric layer 180 may be formed on the lower electrodes 170 and the supporter layers 171 and 172. The dielectric layer 180 may be formed to cover surfaces of the lower electrodes 170 and surfaces of the supporter layers 171 and 172 with a conformal thickness. After the dielectric layer 180 is formed, an upper electrode 190 may be formed on the dielectric layer 180. Accordingly, a capacitor structure CAP including the lower electrodes 170, the dielectric layer 180, and the upper electrode 190 may be formed on the lower structure, and the semiconductor device 100 including the same may be manufactured.

According to the aforementioned example embodiments, since the lower electrode of the capacitor has a structure protruding from the first supporter layer, a semiconductor device having improved electrical properties and reliability may be provided.

While example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a substrate;
a plurality of lower electrodes on the substrate;
at least one supporter layer in contact with the plurality of lower electrodes;
a dielectric layer on the plurality of lower electrodes and the at least one supporter layer; and
an upper electrode on the dielectric layer, wherein
each of the plurality of lower electrodes includes a first lower electrode and a second lower electrode on the first lower electrode,
the at least one supporter layer includes a first supporter layer in contact with a side surface of an upper region of the first lower electrode, and
a level of an uppermost end of the second lower electrode is higher than a level of an upper surface of the first supporter layer.

2. The semiconductor device of claim 1, wherein at least a portion of an upper surface of the first lower electrode is coplanar with an upper surface of the first supporter layer.

3. The semiconductor device of claim 1, wherein
the first lower electrode has a recess region extending in a downward direction from a central region of an upper surface of the first lower electrode,
the second lower electrode includes a first portion and a second portion,
the first portion fills at least a portion of the recess region,
the second portion extends from the first portion, and
the second portion covers the upper surface of the first lower electrode.

4. The semiconductor device of claim 3, wherein the first portion entirely fills the recess region.

5. The semiconductor device of claim 3, wherein
each of the plurality of lower electrodes further includes a void,
the first portion partially fills the recess region, and
the void is between the first portion and a lower end of the recess region.

6. The semiconductor device of claim 3, wherein
a level of a lower end of the first portion is higher than a level of a lower surface of the first supporter layer, and
the level of the lower end of the first portion is lower than a level of an upper surface of the first supporter layer.

7. The semiconductor device of claim 3, wherein at least a portion of the recess region has a width decreasing downwardly.

8. The semiconductor device of claim 1, wherein
the at least one supporter layer further includes a second supporter layer, and
a level of the second supporter layer is lower than a level of the first supporter layer.

9. The semiconductor device of claim 8, wherein a thickness of the first supporter layer is greater than a thickness of the second supporter layer.

10. The semiconductor device of claim 1, wherein at least a portion of a contact surface between the first lower electrode and the second lower electrode is coplanar with an upper surface of the first supporter layer.

11. The semiconductor device of claim 1, wherein the first lower electrode and the second lower electrode include different materials.

12. The semiconductor device of claim 1, further comprising:
a plurality of word lines extending in a first direction on the substrate; and
a plurality of bit lines extending in a second direction on the substrate, wherein
the second direction intersects the first direction, and
a level of the plurality of lower electrodes is higher than a level of the plurality of word lines and a level of the plurality of bit lines.

13. A semiconductor device, comprising:
a substrate;
a plurality of lower electrodes on the substrate;
at least one supporter layer in contact with the plurality of lower electrodes;
a dielectric layer on the plurality of lower electrodes; and
an upper electrode on the dielectric layer, wherein
the plurality of lower electrodes include a first lower electrode and a second lower electrode,
the second lower electrode is in contact with an upper surface of the first lower electrode,
the at least one supporter layer includes a first supporter layer in contact with a side surface of an upper region of the first lower electrode,
an upper surface of the first supporter layer and an upper surface of the first lower electrode are substantially coplanar with each other, and
a level of an uppermost end of the second lower electrode is higher than a level of an upper surface of the first lower electrode.

14. The semiconductor device of claim 13, wherein an upper surface of the first lower electrode is spaced apart from the dielectric layer by the second lower electrode.

15. The semiconductor device of claim 13, wherein an upper surface of the second lower electrode has a wavy shape.

16. The semiconductor device of claim 13, wherein at least a portion of an upper surface of the second lower electrode has a rounded shape.

17. The semiconductor device of claim 13, wherein at least a portion of an upper surface of the second lower electrode is parallel to an upper surface of the substrate.

18. A semiconductor device, comprising:
a substrate;
a device isolation layer on the substrate, the device isolation layer defining active regions on the substrate, the active regions including first impurity regions and second impurity regions in the active regions;
gate electrodes intersecting the active regions and extending into the device isolation layer, the gate electrodes disposed such that the first impurity regions and the second impurity regions in the active regions are on both sides of the gate electrodes, respectively;
bit lines on the gate electrodes, the bit lines being electrically connected to the first impurity regions;
upper conductive patterns on side surfaces of the bit lines and electrically connected to the second impurity regions;
lower electrodes extending vertically on the upper conductive patterns and connected to the upper conductive patterns, the lower electrodes including a first electrode pattern and a second electrode pattern adjacent to each other;
at least one supporter layer between the first electrode pattern and the second electrode pattern and in contact with the first electrode pattern and the second electrode pattern;
an upper electrode on the lower electrodes; and
a dielectric layer between the lower electrodes and the upper electrode, wherein
the at least one supporter layer includes a first supporter layer and a second supporter layer on the first supporter layer,
each of the first electrode pattern and the second electrode pattern includes a first lower electrode and a second lower electrode on the first lower electrode,
a level of an uppermost end of the second lower electrode is higher than a level of an upper surface of the second supporter layer, and
the second lower electrode covers at least a portion of the upper surface of the first lower electrode.

19. The semiconductor device of claim 18, wherein the first lower electrode and the second lower electrode include different materials.

20. The semiconductor device of claim 18, wherein at least a portion of an upper surface of the second lower electrode has a rounded shape.
